(19) United States
(12) Patent Application Publication
(10) Pub. No.: US 2006/0273327 A1
(43) Pub. Date: Dec. 7, 2006

(54) Light emitting diode

(75) Inventor: Jin Seo Im, Seoul (KR)

Correspondence Address: BUCHANAN, INGERSOLL & ROONEY PC, POST OFFICE BOX 1404, ALEXANDRIA, VA, 22313-1404, US

(73) Assignee: Samsung Electro-mechanics Co., Ltd., Suwon-si (KR)

(21) Appl. No.: 11/432,411

(22) Filed: May 12, 2006

(30) Foreign Application Priority Data
Jun. 2, 2005 (KR) 10-2005-0047198

(51) Int. Cl. H01L 33/00

(52) U.S. Cl. 257/79

(57) ABSTRACT

A light emitting diode is provided. The light emitting diode includes: a n-type semiconductor layer; a p-type semiconductor layer facing the n-type semiconductor layer; an active layer formed between the n-type semiconductor layer and the p-type semiconductor layer; and a nanopattern metal layer that is formed in a predetermined pattern on a surface of one of the n-type semiconductor layer and the p-type semiconductor layer, from which light is generated by the active layer, and changes a light path to improve the light extraction efficiency. Thus the light extraction efficiency of the light emitting diode is improved.

### CROSS-REFERENCE TO RELATED PATENT APPLICATION

This application claims the benefit of Korean Patent Application No. 10-2005-0047196, filed on Jun. 2, 2005, in the Korean Intellectual Property Office, the disclosure of which is incorporated herein in its entirety by reference.

### BACKGROUND OF THE DISCLOSURE

1. Field of the Disclosure

The present disclosure relates to a light emitting diode, and more particularly to a light emitting diode with an improved structure for increasing the light extraction efficiency.

2. Description of the Related Art

Light emitting diodes are widely used in optical communication, in data transmission, data recording, and data reading in an apparatus such as compact disk players (CDP) and digital versatile disc players (DVDP). The light emitting diodes can be used for large-sized exterior electric signs or backlights for liquid crystal displays (LCDs).

FIG. 1 illustrates a conventional light emitting diode. Referring to FIG. 1, the light emitting diode 10 includes a substrate 11, and an n-type semiconductor layer 12, an active layer 13 which generates light, and a p-type semiconductor layer 14 sequentially stacked on the substrate 11. An n-type electrode 15 and a p-type electrode 16 electrically contact the n-type semiconductor 12 and the p-type semiconductor 14, respectively.

The light generated by the active layer 13 is emitted to the outside either via the p-type semiconductor 14 and the p-type electrode 16 or the n-type semiconductor layer 12 and the substrate 11. When the light passes through the p-type semiconductor 14 and the p-type electrode 16 to the outside, light having a greater emission angle than a critical angle at which a total reflection occurs on a boundary surface of the p-type semiconductor layer 14 and the p-type electrode 16 from among the light generated by the active layer 13, is reflected repeatedly in a space between the p-type electrode 16 and the substrate 11. Thus, the energy of the light is absorbed into the p-type electrode 16 or other elements and thus the intensity of the light is rapidly decreased. Accordingly, the light extraction efficiency of the light emitting diode is decreased.

### SUMMARY OF THE DISCLOSURE

The present invention may provide a light emitting diode including a nanopattern metal layer to change the path of a light generated by an active layer to the increase light extraction efficiency, and thus to increase the light output efficiency.

According to an aspect of the present invention, there is provided a light emitting diode comprising: a n-type semiconductor layer; a p-type semiconductor layer facing the n-type semiconductor layer; an active layer formed between the n-type semiconductor layer and the p-type semiconductor layer; and a nanopattern metal layer that is formed in a predetermined pattern on a surface of one of the n-type semiconductor layer and the p-type semiconductor layer, from which light is generated by the active layer, and changes a light path to improve light extraction efficiency.

According to another aspect of the present invention, there may be provided a light emitting diode comprising: a n-type semiconductor layer and a p-type semiconductor layer formed on each side of an active layer; a p-type electrode formed to electrically contact the p-type semiconductor layer and reflecting the light generated by the active layer; a substrate placed outside of the p-type electrode; an n-type electrode formed to electrically contact the n-type semiconductor layer; and a nanopattern metal layer formed in a predetermined pattern on a surface facing the n-type electrode of the n-type semiconductor layer and changing a path of the light generated by the active layer to improve the light extraction efficiency.

According to another aspect of the present invention, there may be provided a light emitting diode comprising: an n-type semiconductor layer and a p-type semiconductor layer formed on each of both sides of an active layer; a substrate placed outside the p-type electrode; a reflection layer disposed on a side of the n-type semiconductor layer to reflect the light generated in the active layer; an n-type electrode formed to electrically contact the exposed surface of the n-type semiconductor layer; a p-type electrode formed to electrically contact the p-type semiconductor layer; and a nanopattern metal layer formed in a predetermined pattern on a surface facing the p-type electrode of the p-type semiconductor layer and changing a path of the light generated by the active layer to improve the light extraction efficiency.

### BRIEF DESCRIPTION OF THE DRAWINGS

The above and other features and advantages of the present invention will be described in detailed exemplary embodiments thereof with reference to the attached drawings in which:

FIG. 1 illustrates a conventional light emitting diode;

FIG. 2 is a perspective view of a light emitting diode according to an embodiment of the present invention;

FIG. 3 illustrates a light output increase ratio of the light emitting diode of FIG. 2 according to the distances between the stripes of the nanopattern metal layer;

FIG. 4 is a perspective view of a modified example of the nanopattern metal layer of FIG. 2;

FIG. 5 is a perspective view of another modified example of the nanopattern metal layer of FIG. 2;

FIG. 6 is a perspective view of another modified example of the nanopattern metal layer of FIG. 2;

FIG. 7 is a perspective view of another modified example of the nanopattern metal layer of FIG. 2;

FIG. 8 is a perspective view of a light emitting diode according to another embodiment of the present invention; and

FIG. 9 is a perspective view of a light emitting diode according to still another embodiment of the present invention.

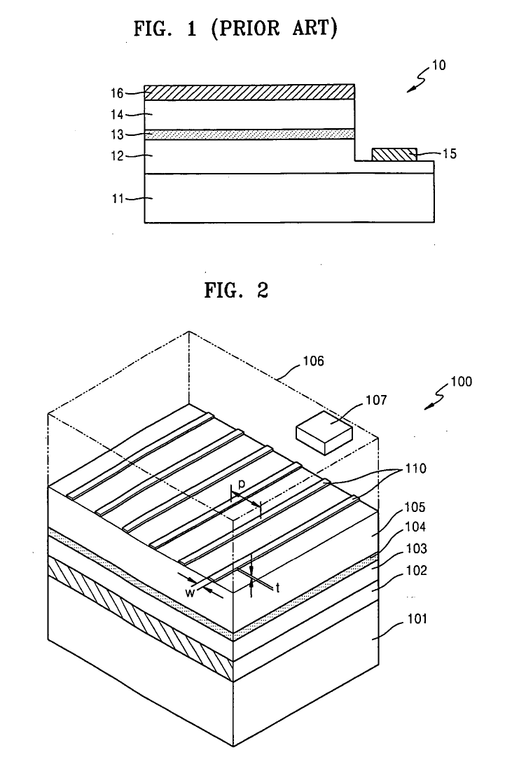

### DETAILED DESCRIPTION OF PREFERRED EMBODIMENTS

The present invention will now be described more fully with reference to the accompanying drawings, in which exemplary embodiments of the invention are shown. In the drawings, the thicknesses of layers and regions are exaggerated for clarity. Like reference numerals in the drawings denote like elements.

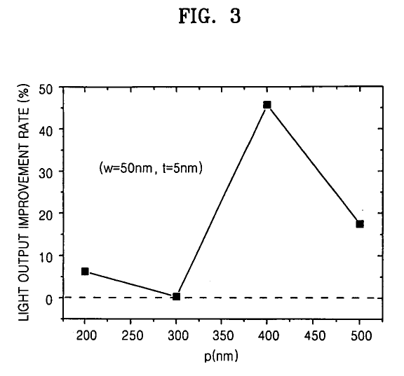

FIG. 2 is a perspective view of a light emitting diode according to an embodiment of the present invention. Referring to FIG. 2, the light emitting diode 100 is a vertical light emitting diode including a substrate 101, and a p-type semiconductor layer 103, an active layer 104, and an n-type semiconductor layer 105 sequentially stacked on the substrate 101. The substrate 101 may be made of a metal such as Cu and Si.

The p-type semiconductor layer 103 may be formed of GaN based III-V nitride compound and may be a direct transition type doped with p-type conductive impurities, and may be for example, a p-GaN layer. The p-type semiconductor layer 103 may be formed of III-V nitride compound and include Al or In in a predetermined ratio of GaN based III-V nitride compound, and may be, for example, an AlGaN layer or an InGaN layer.

The n-type semiconductor layer 105 may be an n-type material layer formed of GaN based III-V nitride compound, and may be an n-GaN layer. The n-type semiconductor layer 105 may be a material layer which includes Al or In in a predetermined ratio with GaN based III-V nitride compound, such as an AlGaN layer or an InGaN layer.

The active layer 104 may be a material layer from which light is emitted by recombination carriers as electrons and protons, i.e., a material layer formed of GaN based III-V nitride compound including a multi quantum well structure, for example an InₓAl_{y}Ga_{1-x-y} N layer (0≦x≦1, 0≦y≦1, and x+y≦1). The active layer 104 may be a material layer which includes Al or In in a predetermined ratio with GaN based III-V nitride compound, such as an InGaN layer. However, the p-type semiconductor layer 103, the active layer 104, and the n-type semiconductor layer 105 are not restricted to the above described examples, and may be formed in various shapes.

A p-type electrode 102 electrically contacts the p-type semiconductor layer 103, and an n-type electrode 105 electrically contacts the n-type electorde 106. That is, the p-type electrode 102 is placed between the p-type semiconductor layer 103 and the substrate 101 to contact the p-type semiconductor layer 103, and the n-type electrode 106 is placed on the n-type semiconductor layer 105 to contact the n-type semiconductor layer 105. Further, a bonding pad 107 connected to an external power source is formed on a portion of the n-type electrode 106.

According to the configuration described above, electrons are injected into the n-type semiconductor layer 105 through the n-type electrode 106, and protons are injected into the p-type semiconductor layer 103 through the p-type electrode 102. The injected electrons and protons meet in the active layer 104 and disappear to generate a light having a short wavelength band. The color of the generated light varies according to the wavelength band, and the wavelength band is set by the energy difference between the conduction band and the valence band of the material which forms the light emitting diode.

The light generated by the active layer 104 can pass through the n-type semiconductor layer 105 and the n-type electrode 106 sequentially, and then be emitted to the outside. In this case, the n-type electrode 106 is formed of a transparent electrode to emit light to the outside. The p-type electrode 102 may be formed of an electrode which can function as a reflection layer to reflect light. The transparent electrode forming the n-type electrode 106 can be formed of an indium tin oxide (ITO).

From the light generated by the active layer 104, passing through the n-type semiconductor layer 105 and the n-type electrode 106, and then emitted to the outside, a portion of light is totally reflected on a boundary surface between the n-type semiconductor layer 105 and the n-type electrode 106 according to an emission angle. This is because the refractive index of the n-type electrode 106 is generally smaller than that of the n-type semiconductor layer 105. Light emitted at an angle greater than the critical angle of total reflection is totally reflected on the boundary surface between the n-type semiconductor layer 105 and the n-type electrode 106. The light, which is totally reflected in such a manner, is repeatedly reflected between the n-type electrode 105 and the p-type electrode 102. Thus, either the energy of the light is reduced or the light is emitted to the lateral side of the n-type electrode 105, and not to the top surface. Accordingly, the light extraction efficiency through the top surface of the n-type electrode 106 is decreased, and consequently, light output of the light emitting diode 100 is decreased.

In the present embodiment, a nanopattern layer 110 is formed between the n-type semiconductor layer 105 and the n-type electrode 106 to improve light extraction efficiency and minimize the amount of light which is totally reflected. The nanopattern layer 110 changes the path of light which is emitted at an incident angle greater than the critical angle under the condition of total reflection calculated from the refractive index between the n-type semiconductor layer 105 and the n-type electrode 106 among the light reaching a surface of the n-type semiconductor layer 105 facing towards the n-type electrode 106 to minimize the amount of light which is totally reflected.

The nanopattern metal layer 110 can be, as illustrated in FIG. 2, formed in a stripe pattern on a surface of the n-type semiconductor layer 105 facing towards the n-type electrode 106. The striped pattern is formed of stripes separated by a distance, with spaces being present between each stripe. The stripes may have a regular width “w”, and are separated by a regular distance “p”. The thickness of the nanopattern metal layer 110 may be less than approximately 100 nm. The nanopattern metal layer 110 may be selected from the group consisting of Au, Ag, Cu, and Al. The pattern of the nanopattern metal layer 110 can be formed and etched using a method such as nano imprinting, e-beam lithography, and holographic lithography.

As the nanopattern metal layer 110 is formed, the nanopattern metal layer 110 can diffract at least a portion of the light which is incident under the condition of total reflection among the light that reaches the surface of the n-type semiconductor layer 105 facing the n-type electrode 106. The diffracted light can be emitted to the outside via the n-type electrode 106, thus improving the light extraction efficiency. The nanopattern metal layer 110 also changes the reflection angle of the reflected light which is not diffracted. As the reflection angle of the light is changed, the light is repeatedly reflected between the n-type electrode 106 and the p-type electrode 102. When the light is incident on the surface facing the n-type electrode 106 of the n-type semiconductor layer 105 at an angle smaller than the critical angle of the total reflection, the light can be emitted via the n-type electrode 106 to the outside, and thus the light extraction efficiency can be improved. Moreover, the nanopattern metal layer 110 provides a surface plasmon wave, which is induced by a portion of the light which is incident under the condition of total reflection among the light that reaches the surface facing n-type electrode 106 of the n-type semiconductor layer 105. The induced surface plasmon wave proceeds along the boundary surface of the n-type semiconductor layer 105 facing the n-type electrode 106 and the nanopattern metal layer 110, and can be emitted to the outside via the n-type electrode 106, thus improving the light extraction efficiency.

The width of the stripes of the nanopattern metal layer 110 may be smaller than the light wavelength of the light generated from the active layer 104. The distance “p” between the stripes may be approximately the same as the light wavelength so that diffraction can easily occur. The distance between the stripes may be greater than the width “w” of the stripes such that the stripes are separated by a sufficient space. The distance “p” may range from one tenth to five times of the light wavelength. The improvement of light extraction efficiency by the nanopattern metal layer 110 can be seen in FIG. 3.

FIG. 3 is a graph illustrating improvement of light extraction according to the distance between the stripes of the nanopattern metal layer 110. Here, the width of the stripes is 50 nm, the thickness of the stripes is 5 nm, and the light wavelength is 400 nm. Referring to FIG. 3, when the distance “p” between the stripes of the nanopattern metal layer 110 is approximately 400 nm, for example, 350 nm as shown in the graph, the light output has increased above 45% compared to a light emitting diode without a nanopattern metal layer. When the nanopattern metal layer 110 is formed, the light output increases overall.

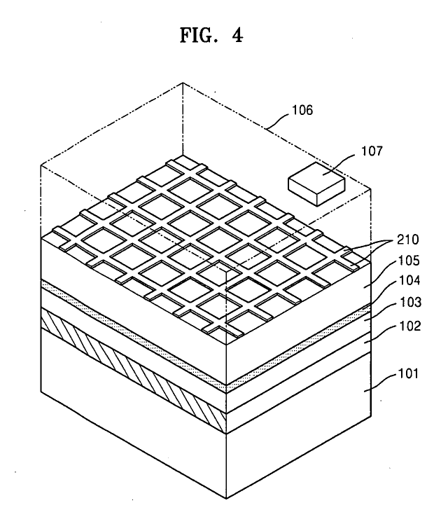

The nanopattern metal layer 110 can be modified in various ways as shown in FIGS. 4 through 7, having the same effect as described above.

The nanopattern metal layer 210 in FIG. 4 is formed on the surface facing the n-type electrode 106 of the n-type semiconductor layer 105 in lattice. The lattice pattern is formed of separated horizontal stripes and separated vertical stripes which cross the horizontal stripes, and there are spaces between each stripe. The horizontal and vertical stripes may respectively have uniform widths and be formed at a regular distance from each other.

The nanopattern metal layer 210 may be selected from the group consisting of Au, Ag, Cu, and Al. The thickness of the nanopattern metal layer 210 may be less than approximately 100 nm. The width of a lattice of the nanopattern metal layer 210, that is the width of the horizontal stripes and the width of the vertical stripes, may be less than the wavelength of the light generated by the active layer 104. The distance between the lattices may be greater than the widths of the horizontal and vertical stripes such that the spaces have sufficient space. Also, the distances between the lattices may range from approximately one tenth to five times of the light wavelength for good diffraction.

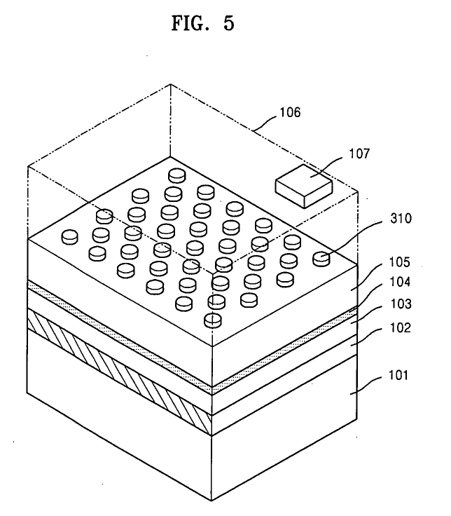

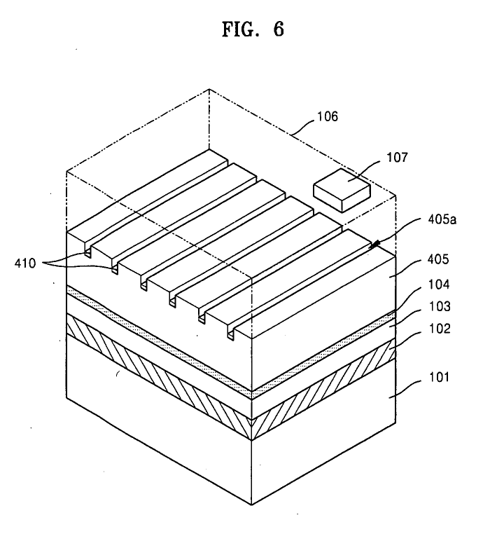

The nanopattern metal layer 310 according to another modified example in FIG. 5 is formed in dot pattern on a surface facing the n-type electrode 106 of the n-type semiconductor layer 105. The dot pattern is formed of staggered dots, and there are spaces between each dot. The dots may have the same size and are formed at a regular distance from each other. The dots in FIG. 5 have a cylindrical shape, but the shape of the dots is not limited to this configuration.

The nanopattern metal layer 310 may be selected from the group consisting of Au, Ag, Cu, and Al, and the thickness of the nanopattern metal layer 310 may be less than approximately 100 nm. The maximum width of the dots of the nanopattern metal layer 310 may be less than the wavelength of the light. The distance between the dots may be set to be greater than the maximum width of the dots.

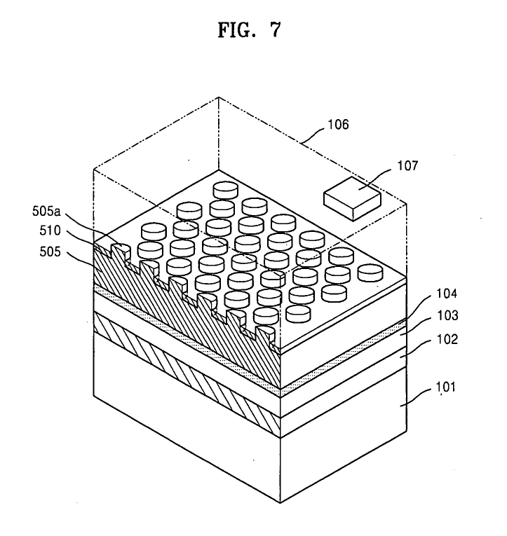

The nanopattern metal layer 410 in FIG. 6 is formed in a corrugated pattern including grooves 405a formed on a surface facing the n-type electrode 406 of the n-type semiconductor layer 405. The n-type semiconductor layer 405 is formed of GaN based III-V nitride compound, and the n-type electrode 406 may be formed of a transparent electrode.

The nanopattern metal layer 410 can be arranged in a stripe pattern as shown in FIG. 6. The nanopattern metal layer 410 may be formed like the nanopattern metal layer 110 in FIG. 2. The nanopattern metal layer 410 may be formed of the nanopattern metal layer 210 in FIG. 4 or the nanopattern metal layer 310 in FIG. 5. The grooves 405a have a width corresponding to the width of the stripes of the nanopattern metal layer 410 and a depth deeper than the thickness of the nanopattern layer 410. However, the sizes are not limited to the above.

The nanopattern metal layer 510 in FIG. 7 is arranged in the spaces between convex bosses 505a formed on a surface facing the n-type electrode 506 of the n-type semiconductor layer 505. The n-type semiconductor layer 505 is formed of GaN based III-V nitride compound, and the n-type electrode 506 may be formed of a transparent electrode.

The maximum width of the bosses 505a is smaller than the wavelength of the light generated by the active layer 104, and is greater than the minimum width of the distance between the bosses 505a. The nanopattern metal layer 510 may be selected from the group consisting of Au, Ag, Cu, and Al, and the thickness of the nanopattern metal layer 510 may be less than approximately 100 nm. In FIG. 7, the bosses 505a are illustrated as to be higher than the nanopattern metal layer 510; however, the bosses 505a can also be as high as or lower than the nanopattern layer 510.

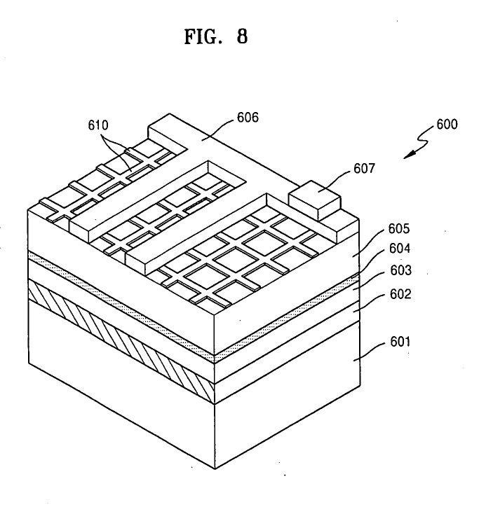

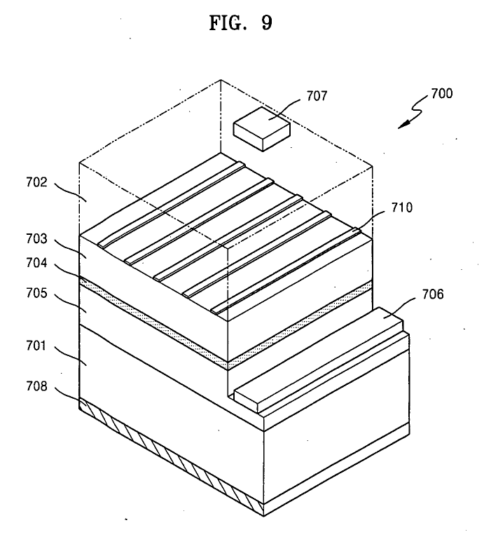

FIG. 8 is a perspective view of a light emitting diode according to another embodiment of the present invention. Referring to FIG. 8, the light emitting diode 600 includes, as in the before-described embodiment, a substrate 601, and a p-type semiconductor layer 603, an active layer 604, and an n-type semiconductor layer 605 sequentially stacked on the substrate 601. The p-type semiconductor layer 603, the active layer 604, and the n-type semiconductor layer 605 may be formed of GaN based III-V nitride compound.

A p-type electrode is placed between the p-type semiconductor layer 603 and the substrate 601 to electrically contact the p-type semiconductor layer 603. The n-type electrode 606 electrically contacts the n-type semiconductor layer 605. In a structure in which the light generated by the active layer 604 is emitted through the n-type semiconductor layer 605 to the outside, the p-type electrode 606 is an electrode which can also be a reflection layer to reflect the light. The n-type electrode 606 is not formed of a transparent electrode formed of ITO which can transmit light as in the before-described embodiment, but is a metal electrode formed of a metal whose line resistance is relatively lower than ITO. Since the light transmittance rate of the n-type electrode 606 is low when the n-type electrode 606 is formed of a metal electrode, the size of the n-type electrode 606 should be optimized such that the area of the n-type semiconductor layer 605 onto which the light is emitted is large enough and electrons can be uniformly supplied to the entire surface of the n-type semiconductor layer 605. A bonding pad 607 can be further formed on a portion of the n-type electrode 606.

A nanopattern metal layer 610 is formed on the surface of the n-type semiconductor layer 605 on which the n-type electrode 606 is formed. The nanopattern metal layer 610 in FIG. 8 has a lattice pattern, however, as described before, the nanopattern metal layer can have a variety of patterns such as a stripe pattern or a dot pattern. The nanopattern metal layer 610 may be formed on a surface of the n-type semiconductor layer 605 where the n-type electrode 606 is not formed, or can be formed on the entire n-type semiconductor layer to be placed on the boundary surface between the n-type semiconductor layer 605 and the n-type electrode 606.

The nanopattern metal layer 610 changes the path of the light emitted at an incident angle greater than the critical angle of the condition of total reflection calculated from the refractive indexes of the n-type semiconductor layer 605 and the n-type electrode 606 among the light reaching a surface of the n-type semiconductor layer 605 facing the n-type electrode 606 as described in the embodiment of FIG. 2 to minimize the amount of light which is totally reflected.

FIG. 9 is a perspective view of a light emitting diode according to another embodiment of the present invention. Referring to FIG. 9, the light emitting diode 700 is a horizontal light emitting diode, including a substrate 701, an n-type semiconductor layer 705, an active layer 704, and a p-type semiconductor layer 703 sequentially. The substrate 701 may be a sapphire substrate, and the n-type semiconductor layer 705, the active layer 704, and the p-type semiconductor layer 703 may be formed of GaN based III-V nitride compound.

An n-type electrode 706 is formed to electrically contact a portion of the n-type semiconductor layer 705. That is, the edges of the n-type semiconductor layer 705 are etched and thus a portion of a surface is exposed, and a n-type electrode 705 is on the exposed surface.

A p-type electrode 702 is formed to electrically contact the p-type semiconductor layer 703. In a structure in which light generated by the active layer 704 is emitted to the outside via the p-type semiconductor layer as in the present embodiment, the p-type electrode 702 is a transparent electrode formed of a material such as ITO to transmit light or is a metal electrode having the same structure as the n-type electrode 606 in FIG. 8. Further, a reflection layer 708 is formed on a surface facing the substrate 701 of the n-type semiconductor layer 705, that is, on the outside of the substrate 701 in FIG. 9. The reflection layer 705 may be placed between the n-type semiconductor layer 705 and the substrate 701. A bonding pad 707 connected to the outer electrical source is formed on a portion of the p-type electrode 702.

A nanopattern metal layer 710 is formed between the p-type electrode 702 and the p-type semiconductor 703. The nanopattern metal layer 710 may be in a stripe pattern as shown in FIG. 9, and in this case, the nanopattern metal layer 710 may be constructed as the nanopattern metal layer 110 of FIG. 2. The nanopattern metal layer 710 may also be formed as the nanopattern metal layer 210 in a lattice pattern in FIG. 4 or as the nanopattern metal layer 310 in a dot pattern in FIG. 5. The nanopattern metal layer 710 may have grooves on a surface facing the p-type electrode 702 of the p-type semiconductor layer 703 and may be formed therein, or bosses are formed on a surface facing the p-type electrode 702 of the p-type semiconductor layer 703 and the nanopattern metal layer 710 may be formed in the space between the bosses.

The nanopattern metal layer 710 changes the path of the light emitted at an incident angle that is greater than the critical angle of the condition of total reflection calculated from the refraction index of the p-type semiconductor layer 703 and the refractive index of the p-type electrode 702 among the light reaching of the p-type semiconductor layer 703 the surface facing the p-type electrode 702 to minimize the amount of light which is totally reflected.

As described above, as a nanopattern metal layer is formed on a surface of a semiconductor layer placed on the side where light generated from the active layer is emitted to the outside to change the path of light, thus the light extraction efficiency is increased. Consequently, the light output of a light emitting diode can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A light emitting diode comprising:
a n-type semiconductor layer;
a p-type semiconductor layer facing the n-type semiconductor layer;
an active layer formed between the n-type semiconductor layer and the p-type semiconductor layer; and
a nanopattern metal layer that is formed in a predetermined pattern on a surface of one of the n-type semiconductor layer and the p-type semiconductor layer, from which the light generated by the active layer passes to the outside, and changes a light path to improve the light extraction efficiency.

2. The light emitting diode of claim 1, wherein the nanopattern metal layer is formed in a stripe pattern.

3. The light emitting diode of claim 2, wherein a width of the stripes is smaller than a wavelength of the light generated by the active layer, and a distance between the stripes is greater than the width of the stripes, ranging from approximately one tenth to five times of a wavelength of the light.

4. The light emitting diode of claim 1, wherein the nanopattern metal layer is formed in a lattice pattern.

5. The light emitting diode of claim 4, wherein a width of the lattice is smaller than a wavelength of the light generated by the active layer, and a distance between the lattices is greater than the width of the lattice, ranging from approximately one tenth to five times of the wavelength of the light.

6. The light emitting diode of claim 1, wherein the nanopattern metal layer is formed in a dot pattern.

7. The light emitting diode of claim 6, wherein a maximum width of the dots is smaller than a wavelength of the light generated by the active layer, and a minimum distance between the dots is greater than the maximum width of the dots.

8. The light emitting diode of claim 1, wherein grooves are formed on a surface of one of the n-type semiconductor layer and the p-type semiconductor layer, on which a nanopattern metal layer is formed, corresponding to the pattern of the nanopattern metal layer.

9. The light emitting diode of claim 1, wherein the groove pattern is selected from the group consisting of stripes, a lattice, and dots.

10. The light emitting diode of claim 1, wherein bosses are formed in a dot shape on a surface of one of the n-type semiconductor layer and the p-type semiconductor layer, on which a nanopattern metal layer is formed, and the nanopattern metal layer is placed in the bosses.

11. The light emitting diode of claim 10, wherein a maximum width of the bosses is smaller than a wavelength of the light generated by the active layer and is greater than a minimum distance between the bosses.

12. The light emitting diode of claim 1, wherein a transparent electrode is formed entirely on a surface of one of the n-type semiconductor layer and the p-type semiconductor layer, on which a nanopattern metal layer is formed, and contacted electrically.

13. The light emitting diode of claim 12, wherein the transparent electrode is formed of indium tin oxide (ITO).

14. The light emitting diode of claim 1, wherein a portion of metal electrode is formed partially on a surface of one of the n-type semiconductor layer and the p-type semiconductor layer, on which a nanopattern metal layer is formed, and contacted electrically.

15. The light emitting diode of claim 14, wherein the nanopattern metal layer is placed outside of the area where the metal electrode is formed.

16. The light emitting diode of claim 1, wherein a reflection layer is formed on an opposite surface of one of the n-type semiconductor layer and the p-type semiconductor layer, on which a nanopattern metal layer is formed, to reflect the light generated by the active layer.

17. The light emitting diode of claim 1, wherein a substrate is placed on an opposite surface of one of the n-type semiconductor layer and the p-type semiconductor layer, on which a nanopattern metal layer is formed.

18. The light emitting diode of claim 1, wherein the n-type semiconductor layer, the active layer, and the p-type semiconductor layer are formed of a GaN based III-V nitride compound.

19. The light emitting diode of claim 1, wherein a thickness of the nanopattern metal layer is approximately 100 nm or smaller.

20. The light emitting diode of claim 1, wherein the nanopattern metal layer is selected from the group consisting of Ag, Au, Al, and Cu.

21. A light emitting diode comprising:
a n-type semiconductor layer and a p-type semiconductor layer formed on each side of an active layer;
a p-type electrode formed to electrically contact the p-type semiconductor layer and reflecting the light generated by the active layer;
a substrate placed outside of the p-type electrode;
an n-type electrode formed to electrically contact the n-type semiconductor layer; and
a nanopattern metal layer formed in a predetermined pattern on a surface facing the n-type electrode of the n-type semiconductor layer and changing a path of the light generated by the active layer to improve light extraction efficiency.

22. A light emitting diode comprising:
an n-type semiconductor layer and a p-type semiconductor layer formed on each of both sides of an active layer;
a substrate placed outside the p-type electrode;
a reflection layer disposed on a side of the n-type semiconductor layer to reflect the light generated in the active layer;
an n-type electrode formed to electrically contact the exposed surface of the n-type semiconductor layer;
a p-type electrode formed to electrically contact the p-type semiconductor layer; and
a nanopattern metal layer formed in a predetermined pattern on a surface facing the p-type electrode of the p-type semiconductor layer and changing a path of the light generated by the active layer to improve the light extraction efficiency.
